(19) United States
(12) Patent Application Publication
(10) Pub. No.: US 2008/0036507 A1
(43) Pub. Date: Feb. 14, 2008

(54) Differential signal transmission and reception circuit capable of reducing power consumption

(76) Inventor: Yasuhiro Yamashita, Fukaya-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/812,744

(22) Filed: Jun. 22, 2007

(30) Foreign Application Priority Data
Aug. 10, 2006 (JP) 2006-218152

(51) Int. Cl. H03F 3/45

(52) U.S. Cl. 327/53; 327/52

(57) ABSTRACT

For dormant periods in which in data is not transmitted to a differential signal reception circuit, an amount of a constant current provided to output buffers of a differential signal transmission circuit is reduced. Consequently, power consumption in the differential signal transmission circuit and the differential signal reception circuit is reduced.

### CROSS-REFERENCE TO RELATED APPLICATIONS

This application is based upon and claims the benefit of priority from Japanese Patent Application No. 2006-218152 filed Aug. 10, 2006; the entire contents of which are incorporated herein by reference.

### BACKGROUND OF THE INVENTION

1. Field of the Invention

The present invention relates to a differential signal transmission and reception circuit capable of reducing power consumption.

2. Description of the Related Art

In recent years, differential signals advantageous for high-speed transmission are used in electronic equipments since it is necessary to transmit a high resolution image in a short time.

For instance, LDVS interface that is one of interfaces for signal transmission of the differential signals is used for signal transmission from a graphic accelerator of a computer to a liquid crystal display device.

RSDS, miniLDVS, and the like that are interfaces for such signal transmission are used between a timing controller and a driver IC in a liquid crystal display device for instance.

As illustrated in FIG. 1, a driver circuit 1A has output buffers 10A, 10B for each differential signal. A receiver circuit 2 has a comparator CMP and an input resistor R for each of the differential signals.

As illustrated in FIG. 2, a timing signal Vin1 that presents a high voltage and a low voltage alternatively is provided to transistors Q3 and Q4 complementary connected with series. A reversing signal Vin2 to the timing signal Vin1 is provided to transistors Q1 and Q2 complementary connected with series.

For an ON period in which the timing signal Vin1 presents the high voltage, the timing signal Vin1 and the reversing signal Vin2 turn the transistors Q3 and Q2 ON respectively. This makes a constant current 121i outputted from a constant current source 121 flows in the transistor Q2, a transmission line Lp, an input resistor R, a transmission line Lm and the transistor Q3 in this order as illustrated by a solid line. In the comparator CMP, a potential of an input terminal of plus polarity is higher than a potential of an input terminal of minus polarity. Consequently, the comparator CMP outputs a high voltage.

On the other hand, for an OFF period in which the timing signal Vin1 presents the low voltage, the timing signal Vin1 and the reversing signal Vin2 turn the transistors Q4 and Q1 ON respectively. This makes the constant current 121i flows in the transistor Q4, the transmission line Lm, the input resistor R, the transmission line Lp and the transistor Q1 in this order as illustrated by a broken line. In the comparator CMP, the potential of the input terminal of plus polarity is lower than the potential of the input terminal of minus polarity. Consequently, the comparator CMP outputs a low voltage.

As mentioned, an output of the comparator CMP changes according to the timing signal Vin1 and the reversing signal Vin2. That is, a differential signal transmission and reception is done.

A differential signal transmission and reception circuit is disclosed in Japanese Unexamined Patent Application Laid-open Nos. 2004-120735 for instance.

By the way, each of the transistors Q1, Q2, Q3 and Q4 in FIG. 2 has resistance element and consumes electrical power according to a current flew in it. In addition, each of the input resistors R consumes electrical power according to a current flew in it. The differential signal transmission and reception circuit having these transistors is configured to be in operation regardless of whether the timing signal Vin1 and the reversing signal Vin2 present a high voltage or a low voltage. Even when a differential signal is unnecessary and the timing signal Vin1 keeps presenting the low voltage, the current illustrated by the broken line in FIG. 2 keeps flowing. That is, the differential signal transmission and reception circuit constantly consumes a current regardless of whether an input signal is provided or not. Therefore, a differential signal transmission and reception circuit like one illustrated in FIG. 2 might consume much electric power.

On the other hand, as for a portable computer, and the like, that has differential signal transmission and reception circuits, there are a lot of one driven by a battery. Therefore, reducing power consumption of a differential signal transmission circuit and a differential signal transmission and reception circuit is hoped for.

The present invention has been made in view of the foregoing points. An object of the present invention is to provide a differential signal transmission circuit capable of reducing power consumption and a differential signal transmission and reception circuit capable of reducing power consumption.

### SUMMARY OF THE INVENTION

A differential signal transmission circuit according to a first aspect of the present invention is characterized by including a constant current source that outputs a constant current; an output circuit that outputs the constant current to one of the transmission lines if an input signal that comes to the output circuit presents a first level and outputs the constant current to the other transmission line if the input signal presents a second level; and a control circuit that reduces an amount of the constant current for periods in which the differential signal is unnecessary.

According to the first aspect of the present invention, power consumption in the output circuit is reduced with the amount of the constant current. Consequently power consumption in the differential signal transmission circuit is reduced.

A differential signal transmission circuit according to a second aspect of the present invention is characterized in that the constant current source is a current mirror circuit that outputs a mirror current of a same amount as the amount of the constant current; and the control circuit reduces the amount of the mirror current for the periods. Others are same as those of the first aspect of the present invention.

According to the second aspect of the present invention, power consumption in the output circuit is reduced with the amount of the mirror current. Consequently power consumption in the differential signal transmission circuit is reduced.

A differential signal transmission and reception circuit according to a third aspect of the present invention is characterized by including a differential signal transmission circuit and a differential signal reception circuit, wherein the differential signal reception circuit receives a current as a differential signal that comes from one of two transmission lines disposed between the differential signal transmission circuit and the differential signal reception circuit and returns the current to the other transmission line; and the differential signal transmission circuit comprises a constant current source that outputs a constant current; an output circuit that outputs the constant current to one of the transmission lines if an input signal that comes to the output circuit presents a first level and outputs the constant current to the other transmission line if the input signal presents a second level; and a control circuit that reduces an amount of the constant current for periods in which the differential signal is unnecessary.

According to the third aspect of the present invention, power consumption in the output circuit and the differential signal reception circuit is reduced with the amount of the constant current. Consequently power consumption in the differential signal transmission and reception circuit is reduced.

A differential signal transmission and reception circuit according to a fourth aspect of the present invention is characterized in that the constant current source is a current mirror circuit that outputs a mirror current of a same amount as the amount of the constant current; and the control circuit reduces the amount of the mirror current for the periods. Others are same as those of the third aspect of the present invention.

According to the fourth aspect of the present invention, power consumption in the output circuit and the differential signal reception circuit is reduced with the amount of the mirror current. Consequently power consumption in the differential signal transmission and reception circuit is reduced.

### BRIEF DESCRIPTION OF THE DRAWINGS

FIG. 1 illustrates a circuit diagram of a circuit including differential signal transmission and reception circuits of the prior art;

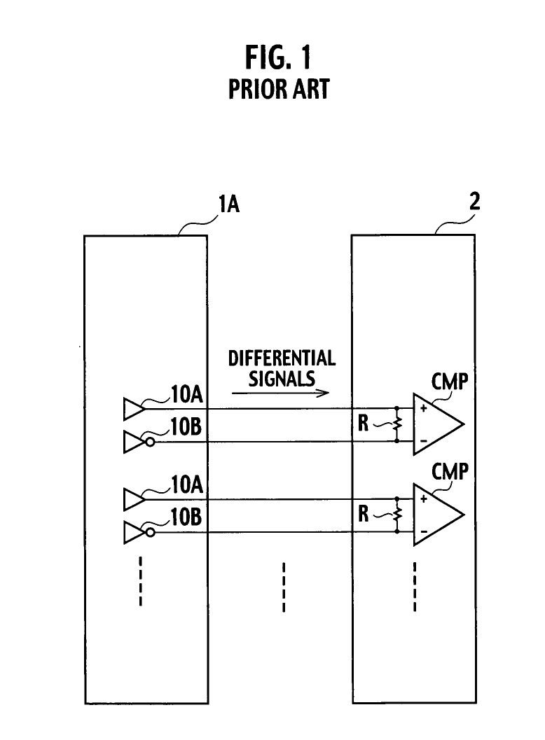

FIG. 2 illustrates a detailed circuit diagram of a part of the circuit in FIG. 1;

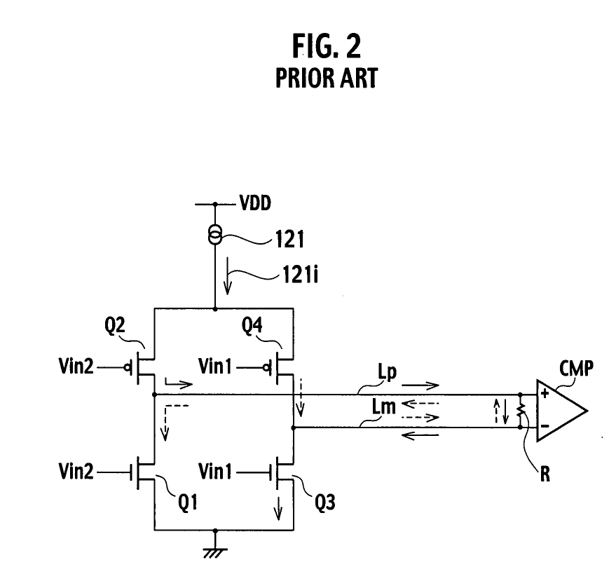

FIG. 3 illustrates a circuit diagram of a circuit including transmission and reception circuits according to an embodiment;

FIG. 4 illustrates a detailed circuit diagram of a part of the circuit in FIG. 3;

FIG. 5 illustrates timing charts of differential signals;

FIG. 6 illustrates a circuit diagram of a modified circuit of the transistors Q1, Q2, Q3 and Q4 in FIG. 4;

### DESCRIPTION OF THE EMBODIMENT

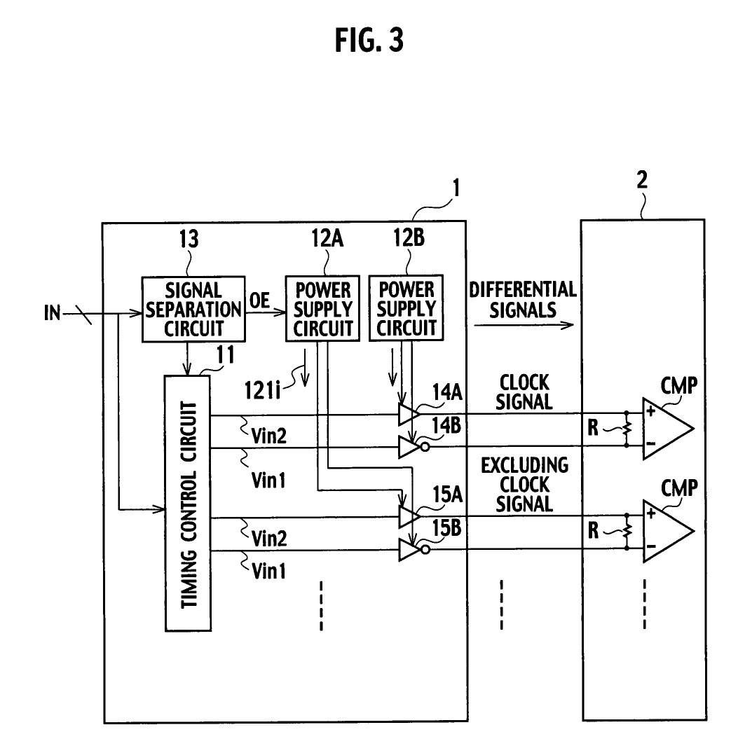

The differential signal transmission and reception circuits according to the embodiment are realized using a driver circuit 1 and receiver circuit 2 illustrated in FIG. 3. Specifically, FIG. 3 illustrates a circuit included in a liquid crystal display device.

The driver circuit 1 has a timing control circuit 11, power supply circuits 12A and 12B, a signal separation circuit 13, output buffers 14A, 14B, 15A and 15B.

The timing control circuit 11 controls timing of signals when the signals are transmitted to the receiver circuit 2 as differential signals. The signals are a vertical synchronizing signal, a horizontal synchronizing signal, both are not illustrated, and a control signal OE all included in input signals IN and the like.

The signal separation circuit 13 separates the control signal OE from the input signals IN and provides the control signal OE to the power supply circuit 12A.

The power supply circuit 12B provides a current to output buffers 14 A and 14 B that transmit a clock signal as a differential signal.

The power supply circuit 12A provides a constant current 121i to each pair of output buffers 15A and 15B that transmit a signal as a differential signal excluding the clock signal.

The receiver circuit 2 has a comparator CMP and an input resistor R for each of the differential signals.

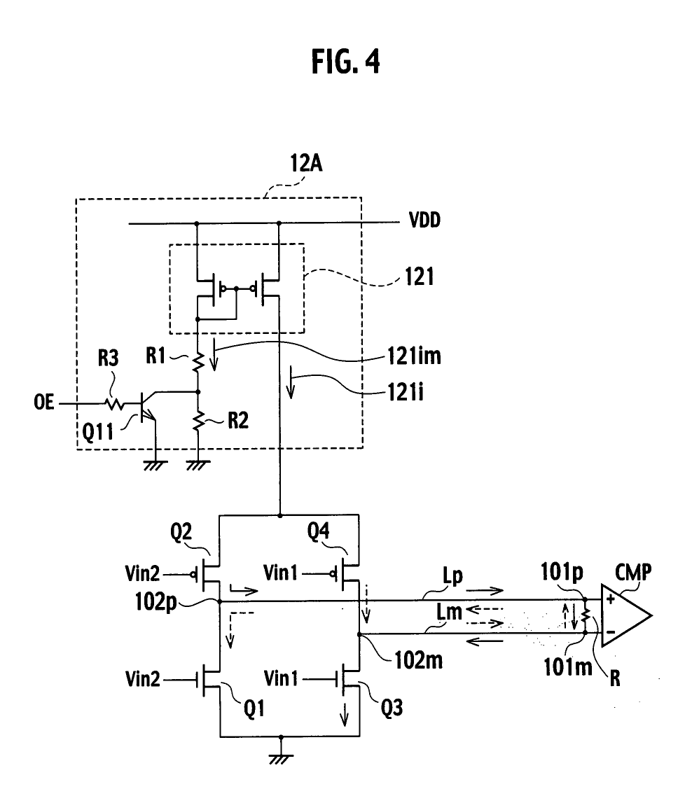

In FIG. 4, a NMOS transistor Q3 and a PMOS transistor Q2 complementary connected with series composes the output buffer 15A, and a NMOS transistor Q1 and a PMOS transistor Q4 complementary connected with series composes the output buffer 15B.

A drain electrode of the transistor Q1 and a source electrode of the transistor Q2 are connected. A drain electrode of the transistor Q3 and a source electrode of the transistor Q4 are connected. Source electrodes of the transistors Q1 and Q3 are grounded.

A constant current source 121 in the power supply circuit 12A generates the constant current 121i using a voltage source VDD and provides the constant current 121i to drain electrodes of the transistors Q2 and Q4.

The constant current source 121 is a current mirror circuit that outputs a mirror current 121im of a same amount as an amount of the constant current 121i.

A serial circuit of resistors R1 and R2 is inserted between a ground and a circuit node which outputs the mirror current 121im.

An emitter electrode of a transistor Q11 is grounded and a collector electrode of the transistor Q11 is connected to a circuit node at which the resistors R1 and R2 are connected.

The control signal OE passes a resistor R3 and is inputted to a base electrode of the transistor Q11.

An input resistor R is connected between an input terminal of plus polarity and an input terminal of minus polarity of a corresponding comparator CMP.

A transmission line Lp is disposed between a circuit node 101p and a circuit node 102p. The circuit node 101p is one at which the input terminal of plus polarity of the comparator CMP and the input resistor R are connected. The circuit node 102p is one at which the drain electrode of the transistor Q1 and the source electrode of the transistor Q2 are connected.

A transmission line Lm is disposed between a circuit node 101m and a circuit node 102m. The circuit node 101m is one at which the input terminal of minus polarity of the comparator CMP and the input resistor R are connected. The circuit node 102m is one at which the drain electrode of the transistor Q3 and the source electrode of the transistor Q4 are connected.

It is said a differential signal transmission circuit bringing the power supply circuit 12A, the transistors Q1, Q2, Q3 and Q4 together. It is said an output circuit bringing the transistors Q1, Q2, Q3 and Q4 together. It is said a differential signal reception circuit bringing the comparator CMP and the input resistor R together. It is said a control circuit bringing the resistors R1, R2, R3, and the transistor Q11 together.

The power supply circuit 12B not illustrated does not use the control signal OE so the power supply circuit 12B is one that the transistor Q11 and the resistor R3 are excluded from the power supply circuit 12A, or one that the resistor R1 or R2 is excluded more.

[Operations]

Next, operations of the transmission and reception circuit will be described.

In FIG. 3, the signal separation circuit 13 separates the control signal OE from the input signal IN and provides the control signal OE to the power supply circuit 12A. In order to transmit the vertical synchronizing signal, the horizontal synchronizing signal, the clock signal, data signal and the like to the receiver circuit 2, the timing control circuit 11 controls timing of these signals.

At this time, the timing control circuit 11 provides a timing signal Vin1 that presents a high voltage and a low voltage alternatively to the output buffers 14B and 15B. On the other hand, the timing control circuit 11 provides a reversing signal Vin2 to the timing signal Vin1 to the output buffers 14A and 15A.

In FIG. 4, the timing signal Vin1 is provided to gate electrodes of the transistors Q3 and Q4 and the reversing signal Vin2 is provided to gate electrodes of the transistors Q1 and Q2. The signals are synchronized to a clock signal made by a PLL (Phase Lock Loop) circuit (not illustrated).

For an ON period in which the timing signal Vin1 presents the high voltage, the timing signal Vin1 and the reversing signal Vin2 turn the transistors Q3 and Q2 ON respectively. This makes the constant current 121i flows in the transistor Q2, the transmission line Lp, the input resistor R, the transmission line Lm and the transistor Q3 in this order as illustrated by a solid line. In the comparator CMP, a potential of the input terminal of plus polarity is higher than a potential of the input terminal of minus polarity. Consequently, the comparator CMP outputs a high voltage.

On the other hand, for an OFF period in which the timing signal Vin1 presents the low voltage, the timing signal Vin1 and the reversing signal Vin2 turn the transistors Q4 and Q1 ON respectively. This makes the constant current 121i flows in the transistor Q4, the transmission line Lm, the input resistor R, the transmission line Lp and the transistor Q1 in this order as illustrated by a broken line. In the comparator CMP, the potential of the input terminal of plus polarity is lower than the potential of the input terminal of minus polarity. Consequently, the comparator CMP outputs a low voltage.

As mentioned, an output of the comparator CMP changes according to the input signal Vin1 and the reversing signal Vin2. That is, transmission and reception of a differential signal is done.

The liquid crystal display device of this embodiment has a liquid crystal panel with a resolution of XGA (eXtended Graphic Array) and is capable of performing interlace scanning and no interlace scanning. For example, the device performs interlace scanning when displaying a still picture, on the other hand, performs no interlace scanning when displaying a moving picture so that the device reduces a total amount of the constant current 121i.

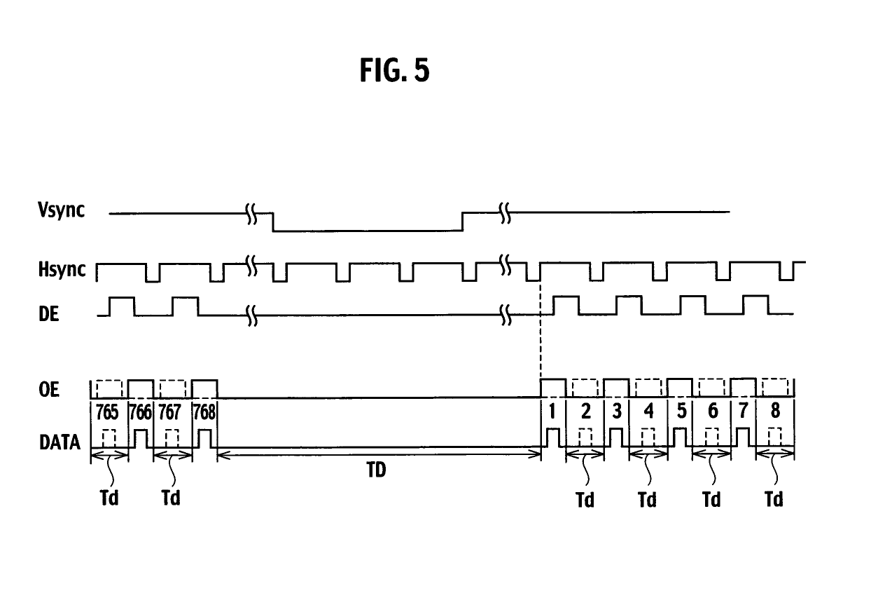

When performing interlace scanning, the driver circuit 1 transmits data of all even line numbers and data of all odd line numbers alternatively by a differential signal DATA illustrated in FIG. 5. FIG. 5 also illustrates the vertical synchronizing signal Vsync, the horizontal synchronizing signal Hsync, the control signal OE and a data enable signal DE.

A period in which the driver circuit 1 transmits the data of all even line numbers and a period in which the driver circuit 1 transmits the data of all odd line numbers are hereinafter referred to as a field of even line numbers and a field of odd line numbers respectively.

In a field of even line numbers, the driver circuit 1 installs a dormant period Td in which the driver circuit 1 does not transmit data between a period in which the driver circuit 1 transmits data of an even line number and a period in which the driver circuit 1 transmits data of a next even line number.

Transmission of the signal DATA is unnecessary for such dormant periods, and the control signal OE presents a low level only for dormant periods to indicate them.

For example, the control signal OE presents a high level as illustrated by a solid line for a period in which the driver circuit 1 transmits data of a line number 766. For a continuing dormant period Td, the control signal OE presents a low level as illustrated by the solid line. For a period in which the driver circuit transmits data of a line number 768, the control signal OE presents a high level as illustrated by the solid line.

The driver circuit 1 installs a dormant period TD between a field of even line numbers and a field of odd line numbers. In a word, the driver circuit 1 installs the dormant period TD between a period in which the driver circuit 1 transmits data of a line number 768 and a period in which the driver circuit 1 transmits data of a line number 1. The control signal OE presents a low level for the dormant period TD. The dormant period TD includes a period in which the vertical synchronizing signal Vsync presents a low level.

In a continuing field of odd line numbers, the driver circuit 1 installs a dormant period Td between a period in which the driver circuit 1 transmits data of an odd line number and a period in which the driver circuit 1 transmits data of a next odd line number.

For example, the control signal OE presents a high level as illustrated by the solid line for a period in which the driver circuit 1 transmits data of a line number 1. For a continuing dormant period Td, the control signal OE presents a low level as illustrated by the solid line. For a period in which the driver circuit 1 transmits data of a line number 3, the control signal OE presents a high level as illustrated by the solid line.

Lastly in the field of odd line numbers, for example, the control signal OE presents a high level as illustrated by a broken line for a period in which the driver circuit 1 transmits data of a line number 765. For a continuing dormant period Td, the control signal OE presents a low level as illustrated by the broken line. For a period in which the driver circuit 1 transmits data of a line number 767, the control signal OE presents a high level as illustrated by the broken line.

The driver circuit 1 installs a dormant period TD between a field of odd line numbers and a field of even line numbers. In a word, the driver circuit 1 installs the dormant period TD between a period in which the driver circuit 1 transmits data of a line number 767 and a period in which the driver circuit 1 transmits data of a line number 2. The control signal OE presents a low level for the dormant period TD. The dormant period TD includes a period in which the vertical synchronizing signal presents a low level.

Firstly in a continuing period of even line numbers, for example, for a period in which the driver circuit 1 transmits data of a line number 2, the control signal OE presents a high level as illustrated by the broken line. For a continuing dormant period Td, the control signal OE presents a low level as illustrated by the broken line. For a period in which the driver circuit 1 transmits data of a line number 4, the control signal OE presents a high level as illustrated by the broken line.

For periods excluding the dormant periods Td and TD, the transistor Q11 in FIG. 4 turns ON since the control signal OE presents a high level. Accordingly, amounts of the constant current 121i and the mirror current 121im become corresponding to a resistance of the resistor R1. Consequently, the amounts of the currents 121i and 121im become large as desired operation can be done.

On the other hand, for the dormant periods Td and TD, the transistor Q11 turns OFF since the control signal OE presents a low level. Accordingly, amounts of the constant current 121i and the mirror current 121im become corresponding to a resistance of the serial circuit of the resistors R1 and R2 and are reduced. Consequently, power consumption in circuits for differential signals excluding the clock signal is reduced.

Reasons are as follows. Each of the transistors Q1, Q2, Q3 and Q4 has resistance element and consumes electrical power according to a current flew in it. An amount of the current is reduced with an amount of the constant current 121i so a power consumption of the transistors Q1, Q2, Q3 and Q4 is reduced. In addition, each of the input resistors R consumes electrical power according to a current flew in it. An amount of the current is reduced with the amount of the constant current 121i so a power consumption of the input resistors R is reduced.

Up to now, a description in terms of reducing power consumption when performing interlace scanning has been done. It is also possible to reduce power consumption when performing no interlace scanning.

Reasons are as follows. One is that there still exists the dormant periods TD even when performing no interlace scanning. In addition, the driver circuit 1 installs a dormant period between a period in which the driver circuit 1 transmits data of a line number such as a number 1 and a period in which the driver circuit 1 transmits data of a next line number such as a number 2 and the control signal OE presents a low level for the dormant periods.

The control signal OE presents a low level as long as the driver circuit 1 does not transmit data by the signal DATA. It is not limited for the dormant periods Td and TD. Thus, power consumption in circuits for differential signals excluding the clock signal is reduced as long as the driver circuit 1 does not transmit data by the signal DATA.

If the constant current 121i stops from flowing, differential signals excluding the clock signal disappears. Even if it is not so, the signals are likely to break off if the amount of the constant current 121i is too small. Therefore, it is preferable to adjust the amount of the constant current 121i so that the signals should not break off.

On the other hand, the power supply circuit 12B keeps providing a current to output buffers 14 A and 14 B that transmit the clock signal without depending on a level of the control signal OE. Therefore, the clock signal does not break off.

As mentioned, reducing an amount of the constant current 121i is achieved by lowering a level of the control signal OE that is provided to the control circuit. It can also be done by stopping the PLL circuit and by keeping the transistors Q1, Q2, Q3 and Q4 off. However, it is necessary to restart the PLL circuit and the PLL circuit is likely to output an unstable clock signal after restart. Therefore, it is preferable not to stop the PLL circuit but to lower a level of the control signal OE.

The present invention is not limited in this embodiment. For example, in place of interlace scanning of every one line, the same scanning of every two or more lines may be done in this embodiment.

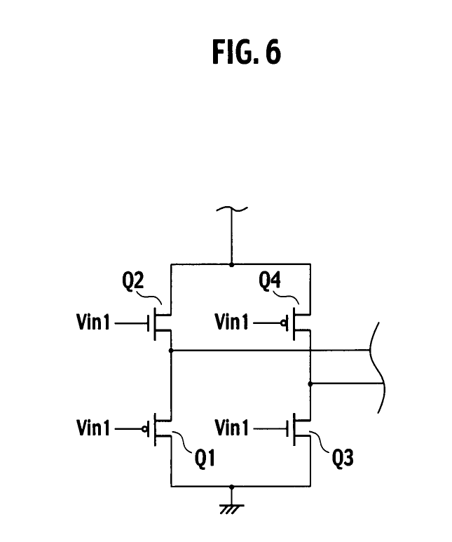

In addition, if a length of the ON period of the timing signal Vin1 equals to a length of the OFF of period of the timing signal Vin1, the reversing signal Vin2 is unnecessary and a circuit of the transistors Q1, Q2, Q3 and Q4 in FIG. 4 can be modified as illustrated in FIG. 6.

As illustrated, the transistors Q1 and Q2 are replaced by a PMOS transistor and a NMOS transistor respectively. The timing signal Vin1 is provided to gate electrodes of all of the transistors Q1, Q2, Q3 and Q4.

For an ON period in which the timing signal Vin1 presents the high voltage, the transistors Q2 and Q3 are ON. Hereafter, a same operation as the operation of the above-mentioned is done.

On the other hand, for the OFF period in which the timing signal Vin1 presents the low voltage, the transistors Q1 and Q4 are ON. Hereafter, a same operation as the operation of the above-mentioned is done.

What is claimed is:

1. A differential signal transmission circuit which is used with a differential signal reception circuit that receives a current as a differential signal that comes from one of two transmission lines disposed between the differential signal transmission circuit and the differential signal reception circuit and returns the current to the other transmission line comprising:
a constant current source that outputs a constant current;
an output circuit that outputs the constant current to one of the transmission lines if an input signal that comes to the output circuit presents a first level and outputs the constant current to the other transmission line if the input signal presents a second level; and
a control circuit that reduces an amount of the constant current for periods in which the differential signal is unnecessary.

2. The differential signal transmission circuit according to claim 1, wherein
the constant current source is a current mirror circuit that outputs a mirror current of a same amount as the amount of the constant current; and
the control circuit reduces the amount of the mirror current for the periods.

3. A differential signal transmission and reception circuit comprising:
a differential signal transmission circuit and a differential signal reception circuit, wherein
the differential signal reception circuit receives a current as a differential signal that comes from one of two transmission lines disposed between the differential signal transmission circuit and the differential signal reception circuit and returns the current to the other transmission line; and
the differential signal transmission circuit comprises
a constant current source that outputs a constant current;
an output circuit that outputs the constant current to one of the transmission lines if an input signal that comes to the output circuit presents a first level and outputs the constant current to the other transmission line if the input signal presents a second level; and
a control circuit that reduces an amount of the constant current for periods in which the differential signal is unnecessary.

4. The differential signal transmission and reception circuit according to claim 3, wherein
the constant current source is a current mirror circuit that outputs a mirror current of a same amount as the amount of the constant current; and
the control circuit reduces the amount of the mirror current for the periods.
